(19) United States
(12) Patent Application Publication
(10) Pub. No.: US 2018/0070697 A1
(43) Pub. Date: Mar. 15, 2018

(54) WALLET-SIZED COMB

(71) Applicant: Heba Designs, LLC dba GO-Comb, Brooklyn, NY (US)

(72) Inventor: Heather Burkman, Brooklyn, NY (US)

(21) Appl. No.: 15/822,277

(22) Filed: Nov. 27, 2017

Related U.S. Application Data
(62) Division of application No. 15/209,040, filed on Jul. 13, 2016.
(60) Provisional application No. 62/192,090, filed on Jul. 14, 2015.

(51) Int. Cl. A45D 24/02; G03F 7/00; A45C 1/08; C23F 1/04

(52) U.S. Cl. CPC A45D 24/02; G03F 7/00; C23F 1/04; A45C 1/08

(57) ABSTRACT

A wallet-sized comb is produced by a method of processing a metal substrate having a thickness similar to a credit card. The method includes receiving a comb design including a top portion and a teeth portion, the teeth portion including a plurality of spaced-apart teeth for combing hair and cutting the metal substrate based on the comb design, the cutting performed using a chemical etching technique, where the metal substrate has a thickness at or below 1.2 millimeter. The method further includes extracting a metal comb from the metal substrate generated from the chemical etching technique and de-burring the metal comb, as well as applying a powder coat finish to the metal comb to generate the wallet comb. The comb design may include a design and/or letters in the top portion, such top portion elements cut also using the chemical etching process.

### RELATED APPLICATIONS

The present invention claims priority to and is a divisional application of U.S. patent application Ser. No. 15/209,040 entitled “WALLET-SIZED COMB” filed Jul. 13, 2016, which relates to and claims priority to U.S. Provisional Patent Application Ser. No. 62/192,090 entitled “CHEMICAL ETCHED WALLET-SIZED COMB” filed Jul. 14, 2015.

### FIELD OF THE INVENTION

The invention relates generally to creating a comb capable of being stored in a wallet.

### BACKGROUND OF THE INVENTION

Most combs, as carried by an individual, tend to be the bendable plastic combs that can fit in a back pocket or a purse. These plastic combs, while beneficial, have numerous shortcomings, including being easily distorted and the tines of the comb bent. The thickness of plastic combs can also be problematic, as well as the size of the comb, thus can easily fall out of a pocket and difficult to find in a purse.

Regarding plastic combs, injection molding has imitations in how thin the material can be without breaking, making the material less ideal for the purpose of making a credit card-sized comb that fits in a wallet. A standard plastic pocket hair comb is 7 mm thick, 7× thicker than a credit card. Most people will not accept adding such a bulky item to their wallet.

One variation, in an attempt to correct the deformity issues of plastic combs is using metal combs. Problems arise with metal combs for at least two reasons. One, the typical metal manufacturing processes render the combs too bulky to comfortably store in a wallet, and two, the metal itself is hard and not conducive to its mains purpose or for storing in a wallet.

Some hair combs are currently made from metal. The primary high-volume manufacturing method currently used in making metal combs is stamping. Metal combs can also be laser cut, a method primarily used for small batch manufacturing and prototyping. The finishing method for these metal combs is a polishing process, creating smoother metal edges.

These techniques for metal combs are problematic because, even if polished, metal combs are still hard feeling on the hair and scalp. This is the primary reason why the polished metal comb is unsuitable for hair combing. Additionally, raw metal, stored in a wallet, scratches credit cards and can render the magnetic strip useless over time.

Furthermore, laser cutting is cost-ineffective, making it an unrealistic manufacturing method for a high-volume business. Especially for highly detailed cutting, such as the shape of a comb. Current laser cut and stamped combs on the market are very thick, on average 5 mm. For metal combs to be stiff and unbendable, this is the required thickness. This thickness is too thick to fit comfortably in a credit card slot in a wallet, as 5 mm is more than five times thicker than a credit card.

As such, there exists a need for a comb having a width similar to a credit card and able to retain a greater degree of stiffness, reduced thickness and a proper etching or coating for a non-abrasive feeling across the user's scalp.

### BRIEF DESCRIPTION OF THE INVENTION

The present invention is a comb manufactured with a novel manufacturing process and having a thickness and size commensurate with a credit card. The manufactured comb can then be readily disposed within a credit card slot of a normal wallet without damaging surrounding credit cards, maintain its proper rigidity and is adequately coated for its intended purpose of combing hair.

The comb is made by using a process called chemical etching onto a metal substrate. The metal substrate has a thickness commensurate with a credit card thickness, approximately 0.8-1.2 mm. The etching of the metal substrate results in cutting the outer shape of the comb, including a plurality of comb teeth. The etching may additionally include a decorative design or logo in a space above the plurality of teeth. Once the etching process is completed, the combs are removed from the metal substrate and are de-burred.

The cut metal substrate is then finished with a thermoset powder coating. Once the powder coating has been applied, the resulting product is the comb as described herein.

### BRIEF DESCRIPTION OF THE DRAWINGS

FIG. 1 illustrates a front view of one embodiment of a wallet-sized comb in accordance with the present invention.

FIG. 2 illustrates a front view of one embodiment of a wallet-sized comb having one of numerous varieties of designs thereon.

FIG. 3 is a photograph showing the etch process.

FIG. 4 is an illustration showing a plurality of combs generated using the etching process.

FIG. 5 is a photograph showing the removal of the etched comb from the plurality of combs in FIG. 4.

FIG. 6 is a flow process describing one embodiment of the comb generation process.

FIG. 7 is an illustration of a finished wallet-sized comb having a powder coat, after it has been heat set.

FIG. 8 is a further illustration of an angled front view of the finished wallet-sized comb having the powder coat thereon.

### DETAILED DESCRIPTION

While the concepts of the present disclosure are susceptible to various modifications and alternative forms, specific exemplary embodiments thereof have been shown by way of example in the drawings and will herein be described in detail. It should be understood, however, that there is no intent to limit the concepts of the present disclosure to the particular forms disclosed, but on the contrary, the intention is to cover all modifications, equivalents, and alternatives consistent with the present disclosure and the appended claims.

References in the specification to “one embodiment,” “an embodiment,” “an example embodiment,” etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to effect such feature, structure, or characteristic in connection with other embodiments whether or not explicitly described.

Improvements in etching and coating techniques now make wallet-sized combs possible. The invention herein includes a wallet-sized or a reduced-thickness comb having a proper etching and coating that solves the shortcomings of the prior art technology.

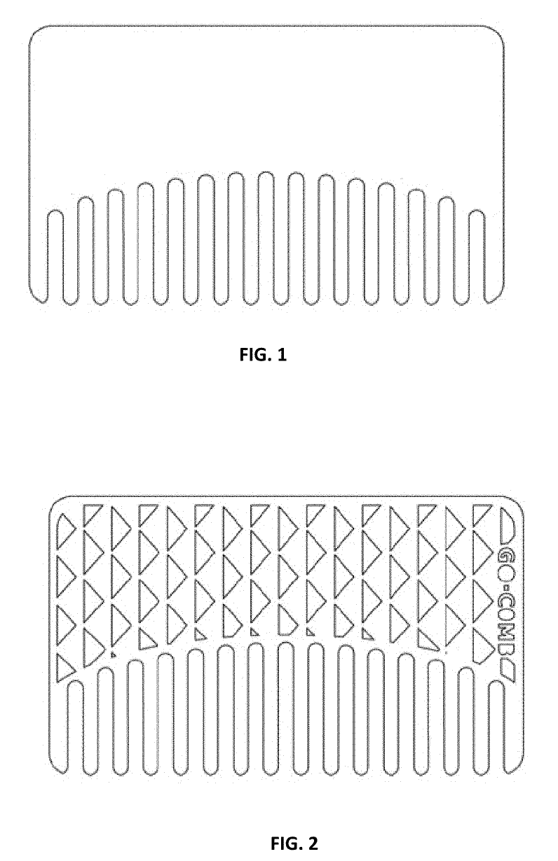

FIG. 1 illustrates an exemplary embodiment of a wallet-sized comb as generated by the process described herein. The comb, while not readily visible in the direct-on view of FIG. 1, has a small thickness approximate with the thickness of a credit card. The comb includes a plurality of teeth allowing for combing the user's hair, but also retains a high degree of rigidity to maintain structural integrity when stored in a wallet. Lastly, as noted below, the comb includes a coating that improves usability by the user, as well as protecting the comb from damaging other items in a user's wallet.

The comb itself is made of numerous edges, for providing varying designs and etching possibilities. FIG. 2 illustrates a plurality of etchings available for varying designs. While FIG. 1 illustrates a general comb, FIG. 2 illustrates one embodiment of an etch design including various design elements and a word or logo. It is recognized that FIG. 2 illustrates one sample design embodiment, but any further design embodiments are within the scope of the present invention. The comb described herein includes a plurality of teeth, but may include any variety of etching above the teeth component. The length of the teeth on the comb may be varied, but the area above the teeth provide structural rigidity for the comb, not only during use but also during storage, such as in a wallet.

The present comb is a metal comb which meets the key quality requirements to make a functional wallet-sized hair comb, including being thin enough to fit easily in a wallet's credit card slot. The comb, as designed, has an appropriate thickness approximate to a credit card, which is 0.76, and proper rigidity to avoid unnecessary breaking or bending while housed inside a wallet. In addition to the thickness, the comb may also have a length and height similar to that of a credit card, so that the comb can fit in a credit card slot of a wallet.

The comb is manufactured by a process called chemical etching, or photo chemical etching. This allows for highly detailed cutting of metal materials, in thicknesses at or below 1.2 mm. FIG. 1 illustrates a general design of the comb and teeth. FIG. 2 illustrates a varying design embodiment with the comb, teeth and cut-out designs above the teeth. The chemical etching process described herein provides for the improved manufacturing process, including the manufacturing of various etching designs, one example illustrated in FIG. 2.

The chemical etching process supports high-volume manufacturing (unlike laser cutting) and allows for finite details in thin materials, which are difficult to do without too much warping in the process of stamping.

The manufactured combs are most frequently produced in the thickness of 0.8 mm-1 mm, incredibly close to the thickness of credit cards (0.76 mm). Such thickness allows for the comb to fit comfortably and indiscernibly in a wallet. Moreover, the thickness of this comb is therefore significantly thinner than all other metal hair combs in the market.

The comb is uniquely suited for chemical etching because its thinness is complemented by its intended “home” of the wallet, providing a stiff environment for the comb to retain its shape. Having a smooth coating, the comb does not damage credit cards or other cards in a person's wallet, as well as providing a smooth surface for comfortable combing of hair.

The present combs are not only created with a unique metal cutting process (compared to other combs) but they are also uniquely finished so as to offer a superior feel to the scalp and hair.

The combs are powder coated, in a second, separate manufacturing process, which creates a smooth, plastic coating over the entire metal comb. This rounds all edges and provides a softer surface, which feels better on hair and the scalp. Additionally, the plastic coating prevents abrasion of the metal against neighboring credit cards in the wallet.

In one embodiment, vector software is used to design the comb, including teeth width, height, as well as a decorative area above the teeth. FIG. 1 illustrates a general comb design, and FIG. 2 illustrates a further embodiment with designs within the decorated area. In one embodiment, the design includes a space to hang the combs during the later coating process, such as the “O” in “GO” as visible in FIG. 2.

Then, a Chemical Etching Manufacturer creates an artwork tool with the 2D design, in the form of a film. Raw material in an 0.8-1 mm thick sheet is then coated with a photo-sensitive resist. The raw material includes a sheet of raw material suitable for the herein described process, including but not limited to brass, stainless steel, aluminum, cooper, nickel, silver, bronze, titanium and nitinol. The above list is exemplary in nature, not expressly limiting, and that other raw material(s) may be usable as recognized by skilled in the art. The two films with the desired etching pattern are applied to the top and bottom surfaces of the material, aligned precisely.

The film is applied to the resist-covered metal sheet. The sheet (which now includes the raw metal, the photo-sensitive resist, and the design film) is exposed to UV light, which hardens the photo-sensitive resist where the design film is clear. The photo-sensitive resist that is not exposed to UV light remains soft. The film is removed from the sheet, and then the sheet is washed such that the remaining soft photo-sensitive resist is removed, leaving only the hardened photo-sensitive resist on the raw metal sheet.

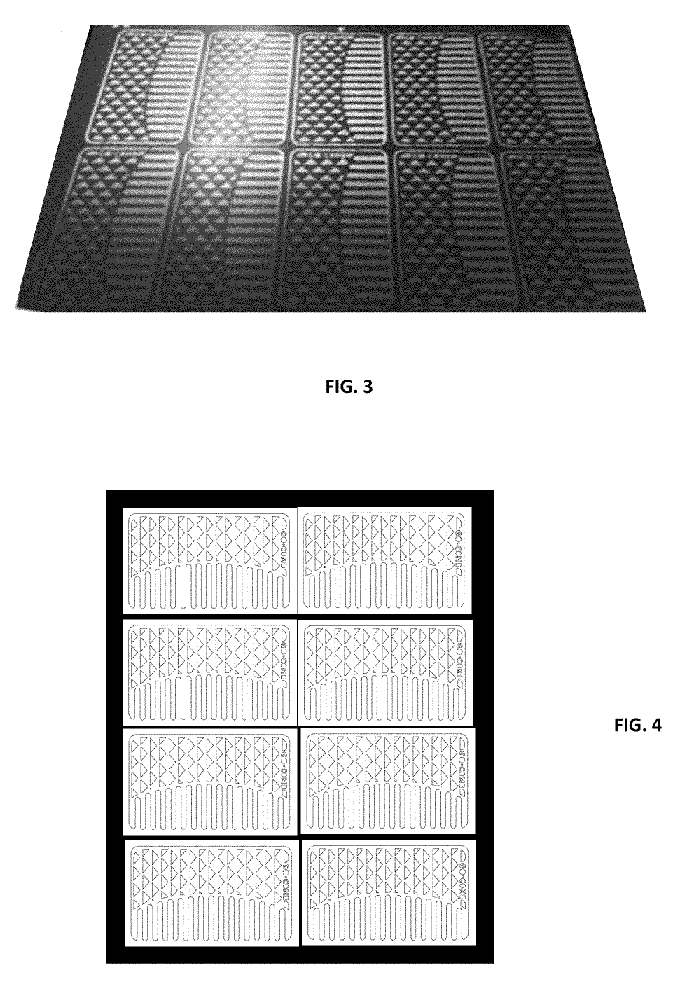

FIG. 3 shows the metal sheet with the photo-sensitive resist hardened with the design. The metal sheet with the hardened resist is then sent through a chemical etching machine, which sprays chemical etchant onto the sheet, and etches away the material not protected by the resist. The amount of time the sheet of metal is exposed to the etchant determines how deeply the design is etched, or even cut all the way through. The chemicals which may be included in the wash include, but are not limited to, H2SO4, HC1, FeC13, CuCl2, NaOH, Cro3, and H3PO4. Different washes are selected based on the base metal material. After the sheet is etched to the desired degree, the sheet is then washed with ammonium hydroxide or carbonated soda to clear the remaining etchant and photo-sensitive resist. Finally the sheet is rinsed with water.

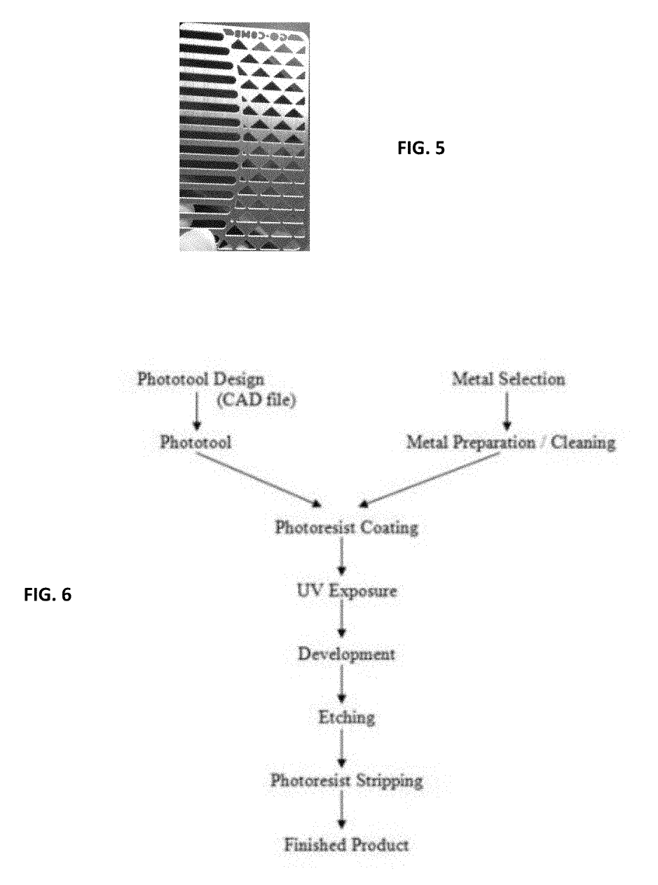

FIG. 4 illustrates the raw metal sheet with etched design. Then the comb pieces are detached from the sheet and deburred. Now you have the comb shape in the raw metal. FIG. 5 shows a comb after it has been separated from the sheet and de-burred.

FIG. 6 shows a flow chart of the photo chemical etching steps, a described herein.

One alternate etching technique includes laser cutting, which uses a 2-D design that etches away or cuts metal using a laser. The disadvantage to laser cutting is that it is slow and expensive, and not ideal for high volumes.

Another etching technique is using a CNC machine (computer numerical control), which uses a rotary cutter to precisely etch or cut metal. When using a CNC machine to cut metals, you need to simultaneously use a coolant while cutting, as well as cut at a slower speed. Therefore, CNC machines are not ideal for high volumes of metal parts, and also cannot achieve as detailed shapes as laser cutting or chemical etching.

Another technique which may be used to create metal parts from a sheet would be stamping, which requires expensive tooling made to the shape of the part, then a machine stamps out the shape from the sheet. This process can be used for high volumes, but it cannot achieve as much detail as chemical etching, and cannot do any sort of decorative etching, where part of the material is etched away vs. cut.

Raw, cut metal combs are then shipped to a powder coating manufacturer. The powder coating manufacturer hangs combs on electrostatically grounded hooks, such as from the “O” in “GO” of FIG. 2. Combs are sprayed with a thermoset powder, which may be any color or clear, by an electrostatic gun, with roughly 1-4 mils of powder. The combs are then sent to an oven of roughly 390 degrees for 20 minutes, which sets the powder into a smooth plastic coating. It is recognized the above powder-coating technique represents one illustrated technique and is not limiting in nature such that any other suitable powder coating technique(s) may be utilized with the herein described comb.

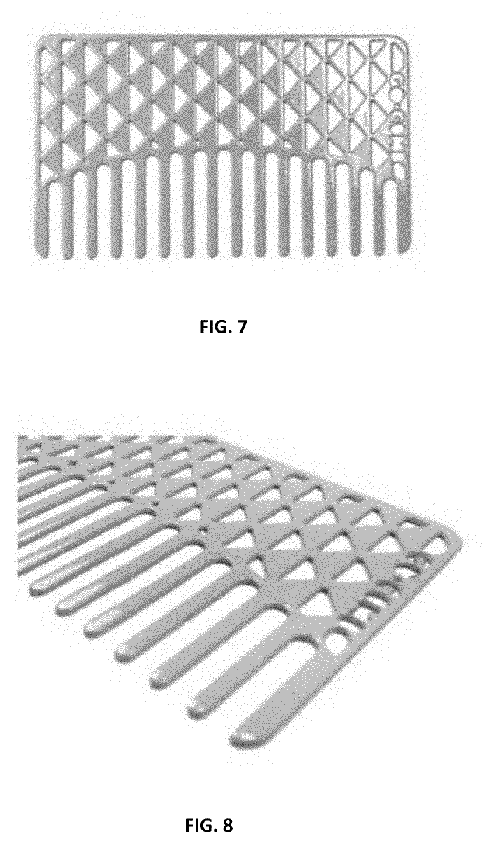

FIGS. 7 and 8 illustrate one embodiment of a finished powder coated wallet comb in the design of FIG. 2. The wallet comb may be powder coated in a variety of colors, including for example in an aqua color.

Once the powder coating process is complete, the combs may then be packaged.

One alternate finishing technique to powder coating may be baked enamel. Enamel paint is sprayed onto the metal surface, and then heat set to better bond the paint to the metal. This is disadvantageous for several reasons: 1) Powder coating provides a thicker coating, which better rounds out rough metal edges and leaves a smoother coating for the purpose of coming hair. 2) Baked enamel process emits toxic VOCs (volatile organic compounds) which are bad to breath and bad for the environment. Powder Coating doesn't emit any VOCs. 3) Powder coating provides a stronger bond between the coating and the metal, making it a more durable finishing process than baked enamel.

As such, the process is herein applicable to a comb in a technique not previously developed. Such technique generates a comb having a minimal thickness at or less than one millimeter, with a proper coating and rigidity for extended use. Whereas, it is recognized that the present technique may be applicable to items having any variety of thickness capable of being processed in the herein described process.

Chemically etched and coated combs are ⅕ to ⅓ the thickness of the old pocket-sized comb, rendering the comb a much more practical and ideal size for a wallet-size comb. Chemically etched and coated combs are stronger and more durable than a plastic comb, and while they may bend a little, they will not break like a plastic comb.

Advantages over other metal combs generally include: these combs are thinner and better suited for in-wallet storage due to the first manufacturing process, chemical etching; and these combs about ½-⅓ the size of other current metal combs which are laser cut or stamped.

Combs of the present invention are finished with a powder coat, which creates a smoother finish on the scalp and hair as well as a protective coating which prevents abrasion to credit cards. Other metal combs are polished, which retains the metal as the outer material, making it very hard and can be abrasive to credit cards, if kept in the wallet.

Alternative embodiments can include coating the chemically etched combs with baked enamel. Baked enamel is the process of applying a wet paint to metal, then baking it dry.

As noted above, the raw material and subsequent comb has a thickness in the range between 0.65 mm and 1.2 mm, sharing a thickness in close approximation with the credit card width of 0.76 mm. The thickness range described herein is one embodiment and not expressly limiting in nature, such that the scope of present invention encompasses combs having a thickness outside the range, but manufactured in the herein-described technique. In addition to the noted thickness, varying embodiments additionally mirror or approximate the height and length of a credit card, 85.60 mm and 53.98 mm. Whereas other embodiments within the scope of the invention may include varying heights or lengths differing from the credit card size, including for example a comb having a height similar to a credit card and a length shorter or longer than a credit card, or in another example the length of the comb is similar to a credit card and a height shorter or longer than a credit card. The height and length of the comb may also vary in different embodiments and designs such that the heights and lengths noted herein are not expressly limiting in nature.

Additionally, the above-described manufacturing and coating of the combs are applicable to any variety of design of the comb itself made originally of the raw material, including the teeth as noted in FIGS. 1-2. For example, the design component of the comb, above the teeth in FIG. 1, may include additional design features, therefore within the scope of the present disclosure. By way of example, the design may be beyond ornamental, including for example etching the raw material to include functional components such as a bottle opener or letter opener edge. Further functional element(s) may be additionally affixed the comb, including for example a reflective mirrored surface in the design portion or the finish of the comb producing a mirror effect. Therefore, the present comb including a comb manufactured under the process described herein, but may additionally include further design and/or functional elements along with the teeth usable for combing hair.

While the disclosure has been illustrated and described in detail in the drawings and foregoing description, such an illustration and description is to be considered as exemplary and not restrictive in character, it being understood that only illustrative embodiments have been shown and described and that all changes and modifications consistent with the disclosure and recited claims are desired to be protected.

Unless defined otherwise, all technical and scientific terms used herein have the same meanings as commonly understood by one of ordinary skill in the art to which this invention belongs. All publications and patents specifically mentioned herein are incorporated by reference in their entirety for all purposes including describing and disclosing the instruments, statistical analyses and methodologies which are reported in the publications which might be used in connection with the invention. All references cited in this specification are to be taken as indicative of the level of skill in the art. Nothing herein is to be construed as an admission that the invention is not entitled to antedate such disclosure by virtue of prior invention.

Although the present invention has been described with reference to preferred embodiments, persons skilled in the art will recognize that changes may be made in form and detail without departing from the spirit and scope of the invention. All references cited throughout the specification, including those in the background, are incorporated herein in their entirety. Those skilled in the art will recognize, or be able to ascertain, using no more than routine experimentation, many equivalents to specific embodiments of the invention described specifically herein. Such equivalents are intended to be encompassed in the scope of the following claims.

What is claimed is:

1. A method for generating a comb capable of being stored in a wallet, the method comprising:
receiving a comb design including a top portion and a teeth portion, the teeth portion including a plurality of spaced-apart teeth for combing hair, the comb design having a length dimension and height dimension commensurate with a credit card length dimension and a credit card height dimension;
cutting a metal substrate based on the comb design, the cutting performed using a chemical etching technique and the metal substrate having a thickness at or below 1.2 millimeters;
extracting a metal comb from the metal substrate generated from the chemical etching technique;
de-burring the metal comb after it is extracted; and
applying a powder coat finish to the metal comb after it is de-burred, therein generating the comb capable of being stored in a wallet.

2. The method of claim 1, wherein the metal substrate has a thickness between 0.65 millimeters and 1.2 millimeters.

3. The method of claim 1, wherein the comb design includes a plurality of letters in the top portion, the method further comprising:
forming the letters in the top portion using the chemical etching technique.

4. The method of claim 1, wherein the metal substrate is made of at least one of: brass, stainless steel, aluminum, cooper, nickel, silver, bronze, titanium and nitinol.

5. The method of claim 1 further comprising:
applying a clear or color powder coat finish to the wallet comb.

6. The method of claim 5 wherein the application of color is performed using a baking process.

7. The method of claim 5 wherein the application of color is performed using a silk screening process.

8. The method of claim 1 further comprising:
applying a plating process to the metal comb to smooth any edges of the metal comb.

9. A method for generating a comb to be stored in a wallet, the method comprising:
receiving a comb design including a top portion and a teeth portion, the teeth portion including a plurality of spaced-apart teeth for combing hair, the top portion including at least one letter designed therein, the comb design having a length dimension and height dimension commensurate with a credit card length dimension and a credit card height dimension;
cutting a metal substrate based on the comb design, the cutting performed using a chemical etching technique and the metal substrate having a thickness between 0.65 millimeters and 1.2 millimeters, the cutting of the metal substrate cutting the teeth in the teeth portion and the at least one letter in the top portion;
extracting a metal comb from the metal substrate generated from the chemical etching technique;
de-burring the metal comb after it is extracted;
applying a powder coat finish to the metal comb after it is de-burred; and
applying a clear or color powder coat finish to the wallet comb, therein generating the wallet comb.

10. The method of claim 1, wherein the metal substrate is made of at least one of: brass, stainless steel, aluminum, cooper, nickel, silver, bronze, titanium and nitinol.

11. The method of claim 9 wherein the application of color is performed using a baking process.

12. The method of claim 9 wherein the application of color is performed using a silk screening process.

13. A method for generating a comb to be stored in a wallet, the method comprising:
receiving a comb design including a top portion and a teeth portion, the teeth portion including a plurality of spaced-apart teeth for combing hair, the top portion including at least one letter designed therein, the comb design having a length dimension and height dimension commensurate with a credit card length dimension and a credit card height dimension;
cutting a metal substrate based on the comb design, the cutting performed using a chemical etching technique and the metal substrate having a thickness between 0.65 millimeters and 1.2 millimeters, the cutting of the metal substrate cutting the teeth in the teeth portion and the at least one letter in the top portion;
extracting a metal comb from the metal substrate generated from the chemical etching technique;
de-burring the metal comb after it is extracted;
applying a powder coat finish to the metal comb after it is de-burred; and
applying a plating process to the metal comb to smooth any edges of the metal comb.

14. The method of claim 13, wherein the metal substrate is made of at least one of: brass, stainless steel, aluminum, cooper, nickel, silver, bronze, titanium and nitinol.
